(19) United States
(12) Patent Application Publication
(10) Pub. No.: US 2020/0020760 A1
(43) Pub. Date: Jan. 16, 2020

(54) SEAL RING INDUCTOR

(71) Applicant: QUALCOMM Incorporated, San Diego, CA (US)

(72) Inventors: Jarred MOORE, San Diego, CA (US); Anton ARRIAGADA, San Marcos, CA (US)

(21) Appl. No.: 16/031,888

(22) Filed: Jul. 10, 2018

(51) Int. Cl. H01L 49/02; H01L 23/00; H01L 23/66; H01L 27/01

(52) U.S. Cl. CPC H01L 28/10; H01L 23/564; H01L 2223/6672; H01L 27/01; H01L 23/66

(57) ABSTRACT

A seal ring includes a first continuous portion having an input terminal and an output terminal. The first continuous portion is configured to operate as an inductor. The seal ring further includes a second portion between the input terminal and the output terminal. The second portion is disconnected from the first continuous portion.

### BACKGROUND

### Field

Aspects of the present disclosure relate to passive devices and, more particularly, to inductors.

### Background

Mobile radio frequency (RF) chips (e.g., mobile RF transceivers) have migrated to a deep sub-micron process node due to cost and power consumption considerations. Designing such mobile RF transceivers becomes complex at this deep sub-micron process node. Designing these mobile RF transceivers is further complicated by added circuit functions for supporting communication enhancements, such as fifth generation (5G) communications. Further design challenges for mobile RF transceivers include analog/RF performance considerations, including mismatch, noise, and other performance considerations. Designs of these mobile RF transceivers may include additional passive devices, for example, for biasing and suppressing resonance, and/or for performing filtering, bypassing, and coupling.

Conventional seal rings in integrated circuits (ICs) provide a hermetic seal during manufacturing to avoid impurities and to keep out moisture. A seal ring can be a continuous ring around a die or it can be broken into pieces. A continuous seal ring is usually connected to ground (GND) for radio frequency (RF) isolation. The seal ring can be broken to reduce parasitic capacitance.

Unfortunately, conventional ICs include many impedance matching components, which occupy a significant area on a chip. It would be advantageous to reduce the number of impedance matching components on the chip while also maintaining and/or improving impedance matching. Therefore, it is desirable to use a seal ring as an on-chip inductor to replace at least some, if not all, of the impedance matching components.

### SUMMARY

A seal ring includes a first continuous portion having an input terminal and an output terminal. The first continuous portion is configured to operate as an inductor. The seal ring further includes a second portion between the input terminal and the output terminal. The second portion is disconnected from the first continuous portion.

A method of fabricating a seal ring includes fabricating a first continuous portion having an input terminal and an output terminal. The method also includes coupling the input terminal to a radio frequency (RF) input. The method further includes fabricating a second portion between the input terminal and the output terminal. The second portion is disconnected from the first continuous portion.

A seal ring includes means for inductance having an input terminal and an output terminal. The seal ring further includes a disconnected portion between the input terminal and the output terminal. The disconnected portion is disconnected from the inductance means.

Additional features and advantages of the present disclosure will be described below. It should be appreciated by those skilled in the art that this present disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a schematic diagram of a radio frequency (RF) front-end module.

FIG. 2 illustrates a conventional module layout.

FIG. 3 illustrates a top view of a seal ring inductor, according to aspects of the present disclosure.

FIG. 4 illustrates a top view of a seal ring inductor, according to aspects of the present disclosure.

FIG. 5 illustrates a top view of a seal ring inductor, according to aspects of the present disclosure.

FIG. 6 illustrates a method of fabricating a seal ring inductor, according to aspects of the present disclosure.

FIG. 7 is a block diagram showing an exemplary wireless communication system in which an aspect of the present disclosure may be advantageously employed.

FIG. 8 is a block diagram illustrating a design workstation used for circuit, layout, and logic design of seal ring inductors according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR”, and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. The term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Conventional complementary metal-oxide-semiconductor (CMOS) technology begins with a front-end-of-line (FEOL) process, in which a first set of process steps are performed for fabricating active devices (e.g., negative MOS (NMOS) or positive MOS (PMOS) transistors) on a substrate (e.g., a silicon on insulator (SOI) substrate). A middle-of-line (MOL) process is performed next, which is a set of process steps that connect the active devices to the back-end-of-line (BEOL) interconnects (e.g., metal layer 1 (M1), M2, M3, M4, . . . Mx) using middle-of-line contacts.

Conventional seal rings in integrated circuits (ICs) provide a hermetic seal during manufacturing to avoid impurities and to keep out moisture. A seal ring can be a continuous ring around a die or it can be broken into pieces. A continuous seal ring is usually connected to ground (GND) for radio frequency (RF) isolation. The seal ring can be broken to reduce parasitic capacitance.

Unfortunately, conventional ICs include many impedance matching components, which occupy a significant area on a chip. It would be advantageous to reduce the number of impedance matching components on the chip while also maintaining and/or improving impedance matching.

Therefore, it is desirable to use a seal ring as an on-chip inductor to replace at least some, if not all, of the impedance matching components.

According to aspects of the present disclosure, a seal ring may be broken so that it may be used as an inductor for impedance matching. Advantages include reduced area on the chip for impedance matching while still providing satisfactory on-chip inductive tuning.

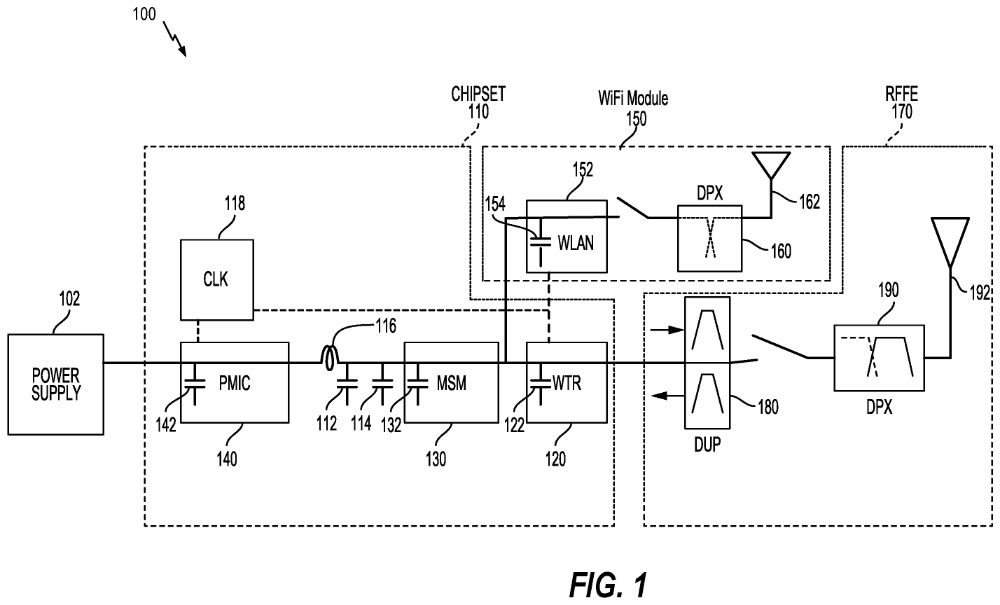

FIG. 1 is a schematic diagram of a wireless device 100 (e.g., a cellular phone or a smartphone) having a seal ring inductor, according to aspects of the present disclosure. The wireless device 100 may include a wireless local area network (WLAN) (e.g., WiFi) module 150 and a RF front-end module 170 for a chipset 110. The WiFi module 150 includes a first diplexer 160 communicably coupling an antenna 162 to a wireless local area network module (e.g., WLAN module 152). The RF front-end module 170 includes a second diplexer 190 communicably coupling an antenna 192 to the wireless transceiver 120 (WTR) through a duplexer 180 (DUP).

The wireless transceiver 120 and the WLAN module 152 of the WiFi module 150 are coupled to a modem (MSM, e.g., a baseband modem) 130 that is powered by a power supply 102 through a power management integrated circuit (PMIC) 140. The chipset 110 also includes capacitors 112 and 114, as well as an inductor(s) 116 (such as the disclosed seal ring inductor) to provide signal integrity. The PMIC 140, the modem 130, the wireless transceiver 120, and the WLAN module 152 each include capacitors (e.g., 142, 132, 122, and 154) and operate according to a clock 118. The geometry and arrangement of the various inductor and capacitor components in the chipset 110 may reduce the electromagnetic coupling between the components.

The wireless transceiver 120 of the wireless device generally includes a mobile RF transceiver to transmit and receive data for two-way communication. A mobile RF transceiver may include a transmit section for data transmission and a receive section for data reception. For data transmission, the transmit section may modulate a RF carrier signal with data to obtain a modulated RF signal, amplify the modulated RF signal using a power amplifier (PA) to obtain an amplified RF signal having the proper output power level, and transmit the amplified RF signal via the antenna 192 to a base station. For data reception, the receive section may obtain a received RF signal via the antenna 192 and may amplify the received RF signal using a low noise amplifier (LNA) and process the received RF signal to recover data sent by the base station in a communication signal.

The wireless transceiver 120 may include one or more circuits for amplifying these communication signals. The amplifier circuits (e.g., LNA/PA) may include one or more amplifier stages that may have one or more driver stages and one or more amplifier output stages. Each of the amplifier stages includes one or more transistors configured in various ways to amplify the communication signals. Various options exist for fabricating the transistors that are configured to amplify the communication signals transmitted and received by the wireless transceiver 120.

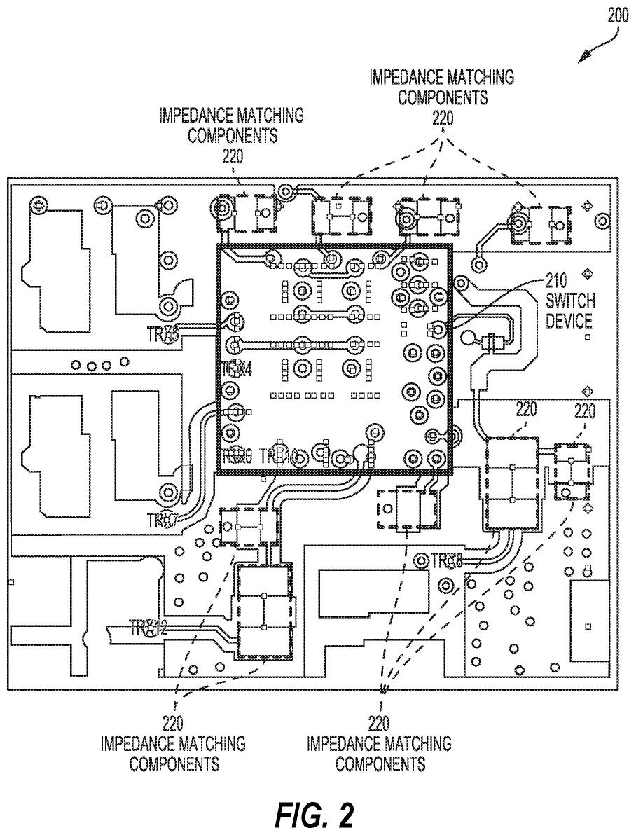

FIG. 2 illustrates a conventional module layout 200. The conventional module layout 200 includes a switch device 210 and several impedance matching components (e.g., 220). The impedance matching components 220 provide impedance matching for the switch device 210. The switch device 210 can be for antenna diversity or an RF switch, for example.

As illustrated, the impedance matching components 220 occupy a significant amount of space on the conventional module layout 200. It is therefore desirable to have impedance matching that is area efficient on the conventional module layout 200.

According to aspects of the present disclosure, a seal ring may be broken so it may be used as an inductor for impedance matching. The seal ring may include a first continuous portion having an input terminal and an output terminal. The first continuous portion may be configured to operate as an inductor. A second portion may be located between the input terminal and the output terminal. The second portion may be disconnected from the first continuous portion.

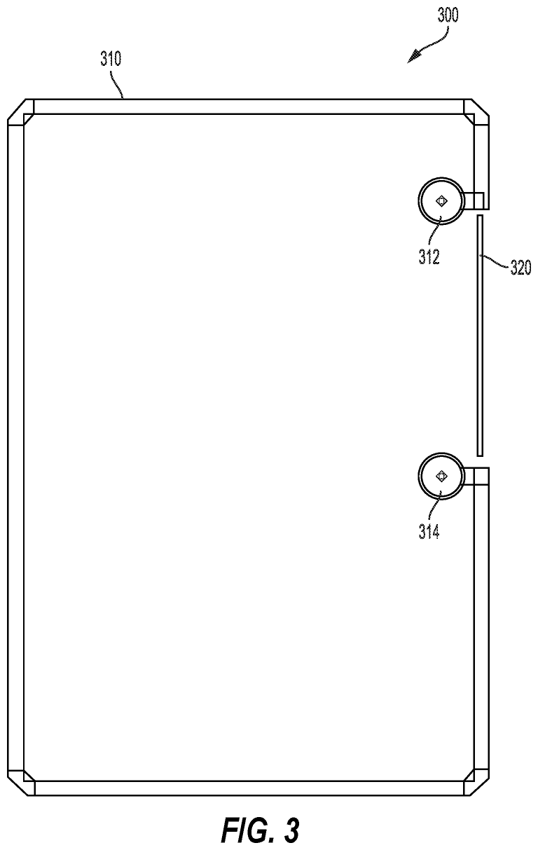

FIG. 3 illustrates a top view of a seal ring inductor 300, according to aspects of the present disclosure. The seal ring inductor 300 includes a first continuous portion 310. The first continuous portion 310 may have one end coupled to an input terminal 312 and another end coupled to an output terminal 314. The first continuous portion 310 is configured to operate as an inductor. For example, breaking the seal ring allows it to be used as an inductor.

A second portion 320 is fabricated between the input terminal 312 and the output terminal 314. The second portion 320 is disconnected from the first continuous portion 310. For example, the second portion 320 may be in a gap between the input terminal 312 and the output terminal 314. The gap between the input terminal 312 and the output terminal 314 may be wider or narrower depending on a desired inductance. The second portion 320 may be shaped as a straight line, or it may be curved or otherwise include turns and/or other shapes.

According to aspects of the present disclosure, each of the first continuous portion 310 and the second portion 320 may be its own inductor, arranged in either a single path or a multipath configuration. The input terminal 312 may be coupled to a radio frequency (RF) input and the output terminal 314 may be coupled to an RF output. Alternatively, the output terminal 314 may be coupled to ground.

According to aspects of the present disclosure, a thickness of the seal ring inductor 300 may be at least four metallization layers. According to additional aspects of the present disclosure, the thickness may be at least double a thickness of a metal three (M3) metallization layer, or at least 80 kilo angstroms.

According to aspects of the present disclosure, the seal ring inductor 300 may be substantially square and/or rectangular shaped. For example, the seal ring inductor 300 may have dimensions of 880 micrometers (μm)×1280 μm, with a width of 25 μm. The first continuous portion 310 may have a same width and/or thickness as the second portion 320. Alternatively, the first continuous portion 310 may have a different width and/or thickness than the second portion 320. Of course, these dimensions are exemplary only, and other sizes are possible. Additionally, the seal ring inductor 300 may be circular, triangular, pentagonal, hexagonal, heptagonal, octagonal, etc., in shape.

Advantages of the seal ring configurations include reduced area on the chip for impedance matching while still providing satisfactory on-chip inductive tuning.

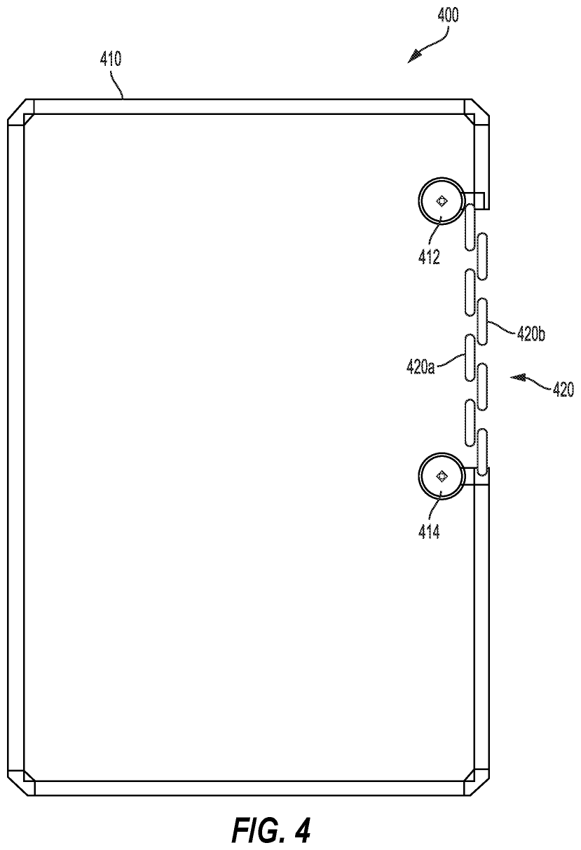

FIG. 4 illustrates a top view of a seal ring inductor 400, according to additional aspects of the present disclosure. The seal ring inductor 400 includes a first continuous portion 410. The first continuous portion 410 may have one end coupled to an input terminal 412 and another end coupled to an output terminal 414. The first continuous portion 410 is configured to operate as an inductor. A second portion 420 is between the input terminal 412 and the output terminal 414. The second portion 420 is disconnected from the first continuous portion 410.

The second portion 420 may be a broken portion having at least one inner discontinuous section 420a and at least one outer discontinuous section 420b. The inner discontinuous section(s) 420a and the outer discontinuous section(s) 420b may be offset from one another. In this way, the broken portion (e.g., 420) is configured to maintain a hermetic seal.

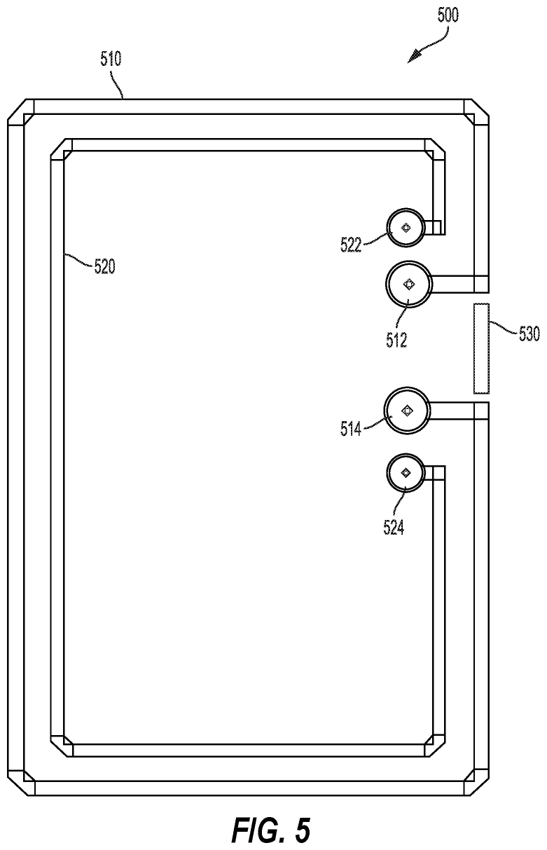

FIG. 5 illustrates a top view of a seal ring inductor 500, according to further aspects of the present disclosure. The seal ring inductor 500 includes a first continuous portion 510. The first continuous portion 510 may have one end coupled to a first input terminal 512 and another end coupled to a first output terminal 514. The first continuous portion 510 is configured to operate as an inductor.

A second continuous portion 520 is inside the first continuous portion 510. The second continuous portion 520 may be coupled to a second input terminal 522 (e.g., a second input) at one end and a second output terminal 524 (e.g., a second output) at another end. The second continuous portion 520 may provide radio frequency (RF) coupling. The second continuous portion 520 may be the same shape as the first continuous portion 510.

The first input terminal 512 may be coupled to an RF input and the first output terminal 514 may be coupled to an RF output. Alternatively, the first output terminal 514 may be coupled to ground. Similarly, the second input terminal 522 may be coupled to an RF input, and the second output terminal 524 may be coupled to an RF output or ground.

In this configuration, a second portion 530 is between the first input terminal 512 and the first output terminal 514. The second portion 530 is disconnected from the first continuous portion 510.

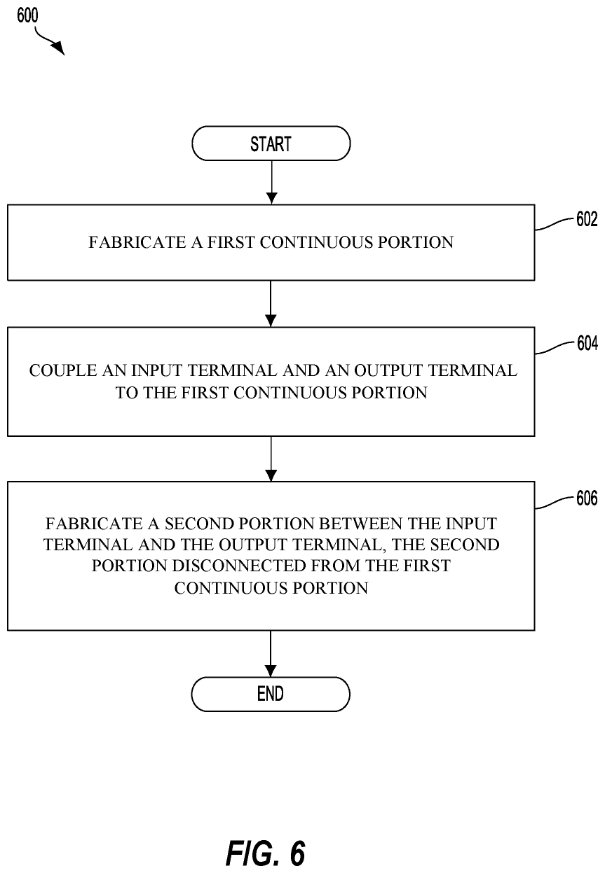

FIG. 6 illustrates a method 600 of fabricating a seal ring inductor, according to aspects of the present disclosure. The method 600 begins at block 602, where a first continuous portion is fabricated. For example, as shown in FIG. 3, the first continuous portion 310 may be a broken seal ring.

At block 604, an input terminal and an output terminal are coupled to the first continuous portion. For example, as shown in FIG. 3, the first continuous portion 310 may be coupled to an input terminal 312 and an output terminal 314.

At block 606, a second portion is fabricated between the input terminal and the output terminal. The second portion is disconnected from the first continuous portion. For example, as shown in FIG. 3, the second portion 320 may be between the input terminal 312 and the output terminal 314.

According to an aspect of the present disclosure, a seal ring is described. In one configuration, the seal ring includes means for inductance. For example, the inductance means may be the first continuous portions 310, 410, and 510 as shown in FIGS. 3-5. In another aspect, the aforementioned means may be any module or any apparatus or material configured to perform the functions recited by the aforementioned means.

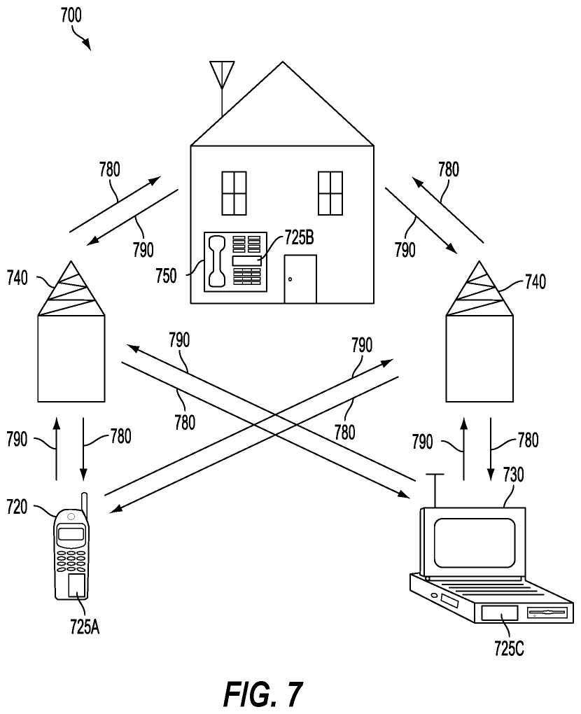

FIG. 7 is a block diagram showing an exemplary wireless communication system 700 in which an aspect of the present disclosure may be advantageously employed. For purposes of illustration, FIG. 7 shows three remote units 720, 730, and 750 and two base stations 40. It will be recognized that wireless communication systems may have many more remote units and base stations. Remote units 720, 730, and 750 include IC devices 725A, 725B, and 725C that include the disclosed seal ring. It will be recognized that other devices may also include the disclosed seal ring, such as the base stations, switching devices, and network equipment. FIG. 7 shows forward link signals 780 from the base station 740 to the remote units 720, 730, and 750 and reverse link signals 790 from the remote units 720, 730, and 750 to base station 740.

In FIG. 7, remote unit 720 is shown as a mobile telephone, remote unit 730 is shown as a portable computer, and remote unit 750 is shown as a fixed location remote unit in a wireless local loop system. For example, the remote units may be a mobile phone, a hand-held personal communication systems (PCS) unit, a portable data unit such as a personal data assistant, a GPS enabled devices, a navigation device, a set top box, a music player, a video player, an entertainment unit, a fixed location data unit such as meter reading equipment, or other devices that store or retrieve data or computer instructions, or combinations thereof. Although FIG. 7 illustrates remote units according to the aspects of the present disclosure, the present disclosure is not limited to these exemplary illustrated units. Aspects of the present disclosure may be suitably employed in many devices, which include the disclosed seal ring.

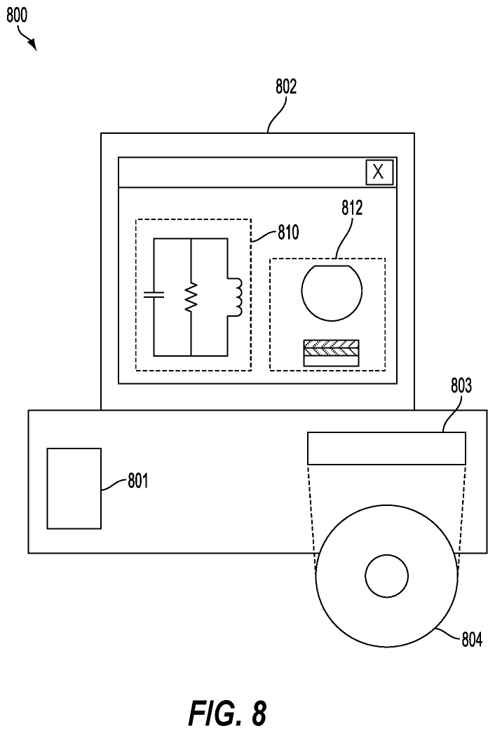

FIG. 8 is a block diagram illustrating a design workstation used for circuit, layout, and logic design of an IC structure, such as the seal ring disclosed above. A design workstation 800 includes a hard disk 801 containing operating system software, support files, and design software such as Cadence or OrCAD. The design workstation 800 also includes a display 802 to facilitate design of a circuit 810 or an IC device 812 including the disclosed seal ring. A storage medium 804 is provided for tangibly storing the design of the circuit 810 or the IC device 812. The design of the circuit 810 or the IC device 812 may be stored on the storage medium 804 in a file format such as GDSII or GERBER. The storage medium 804 may be a CD-ROM, DVD, hard disk, flash memory, or other appropriate device. Furthermore, the design workstation 800 includes a drive apparatus 803 for accepting input from or writing output to the storage medium 804.

Data recorded on the storage medium 804 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 804 facilitates the design of the circuit 810 or the IC device 812 including the disclosed seal ring by decreasing the number of processes for designing semiconductor wafers.

For a firmware and/or software implementation, the methodologies may be implemented with modules (e.g., procedures, functions, and so on) that perform the functions described herein. Machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on non-transitory computer-readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the present disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, and composition of matter, means, methods, and steps described in the specification. As one of ordinary skill in the art will readily appreciate from the present disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the present disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the present disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The steps of a method or algorithm described in connection with the present disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. In addition, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), and Blu-ray disc where disks usually reproduce data magnetically, while discs reproduce data optically with lasers. Combinations of the above should also be included within the scope of computer-readable media.

The previous description of the present disclosure is provided to enable any person skilled in the art to make or use the present disclosure. Various modifications to the present disclosure will be readily apparent to those skilled in the art, and the generic principles defined herein may be applied to other variations without departing from the spirit or scope of the present disclosure. Thus, the present disclosure is not intended to be limited to the examples and designs described herein but is to be accorded the widest scope consistent with the principles and novel features disclosed herein.

What is claimed is:

1. A seal ring, comprising:
a first continuous portion having an input terminal and an output terminal, the first continuous portion configured to operate as an inductor; and
a second portion between the input terminal and the output terminal, the second portion disconnected from the first continuous portion.

2. The seal ring of claim 1, in which the second portion comprises a broken portion having at least one inner discontinuous section and at least one outer discontinuous section, the broken portion configured to maintain a hermetic seal, the at least one inner discontinuous section and the at least one outer discontinuous section offset from one another.

3. The seal ring of claim 1, in which the first continuous portion and the second portion are each configured to operate as separate inductor.

4. The seal ring of claim 1, in which the input terminal is coupled to a radio frequency (RF) input and the output terminal is coupled to an RF output.

5. The seal ring of claim 1, in which the input terminal is coupled to a radio frequency (RF) input and the output terminal is coupled to ground.

6. The seal ring of claim 1, in which a thickness of the seal ring is at least four metallization layers.

7. The seal ring of claim 1, in which a thickness of the seal ring is at least double a thickness of a metal three (M3) metallization layer.

8. The seal ring of claim 1, in which a thickness of the seal ring is at least 80 kilo angstroms.

9. The seal ring of claim 1, further comprising a second continuous portion inside the first continuous portion, the second continuous portion having a second input and a second output.

10. The seal ring of claim 1, integrated into a mobile phone, a set top box, a music player, a video player, an entertainment unit, a navigation device, a computer, a hand-held personal communication systems (PCS) unit, a portable data unit, and/or a fixed location data unit.

11. A method of fabricating a seal ring comprising:
fabricating a first continuous portion having an input terminal and an output terminal;
coupling the input terminal to a radio frequency (RF) input; and
fabricating a second portion between the input terminal and the output terminal, the second portion disconnected from the first continuous portion.

12. The method of claim 11, in which fabricating the second portion comprises fabricating a broken portion having at least one inner discontinuous section and at least one outer discontinuous section, the broken portion configured to maintain a hermetic seal, the at least one inner discontinuous section and the at least one outer discontinuous section offset from one another.

13. The method of claim 11, further comprising coupling the output terminal to an RF output.

14. The method of claim 11, further comprising coupling the output terminal to ground.

15. The method of claim 11, further comprising fabricating a second continuous portion inside the first continuous portion, the second continuous portion having a second input and a second output.

16. The method of claim 11, in which the seal ring is integrated into a mobile phone, a set top box, a music player, a video player, an entertainment unit, a navigation device, a computer, a hand-held personal communication systems (PCS) unit, a portable data unit, and/or a fixed location data unit.

17. A seal ring, comprising:
means for inductance having an input terminal and an output terminal; and
a disconnected portion between the input terminal and the output terminal, the disconnected portion disconnected from the inductance means.

18. The seal ring of claim 17, in which the disconnected portion comprises a broken portion having at least one inner discontinuous section and at least one outer discontinuous section, the broken portion configured to maintain a hermetic seal, the at least one inner discontinuous section and the at least one outer discontinuous section offset from one another.

19. The seal ring of claim 17, in which the disconnected portion is configured to operate as an inductor.

20. The seal ring of claim 17, integrated into a mobile phone, a set top box, a music player, a video player, an entertainment unit, a navigation device, a computer, a hand-held personal communication systems (PCS) unit, a portable data unit, and/or a fixed location data unit.
